(19) United States
(12) Patent Application Publication
(10) Pub. No.: US 2009/0020067 A1
(43) Pub. Date: Jan. 22, 2009

(54) METHOD OF MANUFACTURING SOLAR-GRADE POLYSILICON INGOT WITH RELEVANT INDUCTION APPARATUS

(76) Inventors: Zhi-Yi SU, (US); Yong-Qiang Hong, Xiamen City (CN); Ji-Rong Yang, Xiamen (CN)

Correspondence Address: Dr. BANGER SHIA;Int''l Patent Office of Bang Shia, 102 Lindencrest Ct, Sugar Land, TX, 77479-5201, US

(21) Appl. No.: 12/049,449

(22) Filed: Mar. 17, 2008

(30) Foreign Application Priority Data
Jul. 17, 2007 (CN) 200710009238.0

(51) Int. Cl. C30B 33/00; C30B 9/04

(52) U.S. Cl. 117/3; 117/81

(57) ABSTRACT

The present invention pertains to a method of producing solar-grade polysilicon ingot conducive to reduce the energy consumption and cost and have high yield of casting ingot without complicating equipments. It includes melting and heating raw materials into raw water; mixing the slag removal with the water for eliminating metal impurities; conducting some water vapor for obviating B-atomic and generating pure water, thereafter heated from 1500°-1700° C.; advance heating the crucible and graphite mold in the temperature range of 1000°-1400° C., further pouring the pure water therein and having water temperature from 1450°-1600° C.; adjusting the temperature of the crucible and mold from 1400°-1430° C., thence to the range of 1000°-1200° C. for concentrating the solid/liquid property and impurities of the water on central of the mold; reducing the temperature of the crucible range of 1000°-1200° C. to 200°-400° C., thus finishing an integral polysilicon ingot.

### BACKGROUND OF THE INVENTION

1. Field of the Invention

The invention patent relates to a method of manufacturing solar-grade polysilicon ingot with relevant induction apparatus.

2. Description of the Related Art

Recently, there has been a trend among the PV (photovoltaic) industry towards a large demand of the solar-grade polysilicon, and it becomes popular around the word in producing solar-grade polysilicon with lower energy consumption and manufacturing cost. Generally, polysilicon ingots are commonly formed by directional solidification method and heat exchanging method; however, both these two methods usually require complicating and expensive equipments but produce fewer quantities of ingots with higher unit prices. In view of the above problems, the industry dedicates to develop a method for producing more than 1 ton of ingots without expensive and complicating equipments, thereby decreasing the consumption of the energy and investing cost, further increasing the yield rate and the producing efficiency.

### SUMMARY OF THE INVENTION

The purpose of the present invention is to provide a process of casting solar-grade polysilicon ingot which facilitates to decrease the energy consumption and manufacturing cost with uncomplicated equipments, simultaneously to increase the yield rate of the ingots.

The present invention includes a method of fabricating solar-grade polysilicon ingot with relevant induction apparatus comprising the steps of:

(1) charging raw silicon materials or liquidized silicon into an induction furnace for melting the raw materials into raw silicon water or heating said liquidized silicon; wherein, it is preferably restricted to have 1 to 3 tons of the raw silicon materials and utilize 1 to 6 induction furnaces in operation, and the furnaces can be medium frequency induction furnaces.

(2) arranging a certain amount of solar-grade silicon slag removal into said furnace for mixing with said raw silicon water, thereby eliminating P-atomic(phosphorus) and other metal impurities inherent within said raw silicon materials; wherein, the solar-grade silicon slag removal is comprised of either one or two following materials, for instance of CaSiO3 (Calcium Silicate), Na2SiO3 (Sodium Silicate), BaCO3 (Barium Carbonate), and Na2B4 O7.10H2O (Borax), and the ratio of the raw silicon water to the silicon slag removal is preferably at 100:2-15.

(3) conducting some water vapor into the raw silicon water inside the furnace, further attaining a pure silicon water by obviating B-atomic (boride); wherein, the water vapor flow is 3.5 L-60 L/min, and total time for conducting the water vapor requires 5 to 40 minutes, preferably at 30 minutes;

(4) heating said pure silicon water for attaining a water temperature range from 1500° C. to 1700° C., preferably at 1650° C.;

(5) predetermining an ingot casting crucible and a graphite mold disposed therein to be electrically heated in a temperature range between 1000° C. and 1400° C., then pouring the pure silicon water into the graphite molds; wherein, the ingot casting crucible preferably reaches at 1350° C.;

(6) retaining the pure silicon water in said crucible and controlling said water temperature range of 1450°-1600° C.; wherein, said pure silicon water is retained within said crucible for about 1 to 2 hours and said water temperature is controlled, preferably at 1550° C.;

(7) adjusting said crucible and said molds to attain said temperature range from 1400° C. to 1430° C., preferably at 1420° C.;

(8) decreasing the temperature of said crucible and said molds gradient in 1000°-1200° C., thus generating a solid/liquid surface and interface property within the pure silicon water which would forward to a central of the mold; the metal impurities would also concentrate on the central thereof; wherein, the temperature of the ingot casting crucible and the graphite mold is decreased gradient within a range of 5°-50° C./h.

(9) gradually reducing the temperature of the crucible for solidifying the pure silicon water into a crystallized ingot; further retaining said ingot inside said crucible in the temperature range from 1000-1200° C. until reaching the range of 200-400° C., and thereafter taking out and cooling the crystallized ingot, thus finishing an integral solar-grade polysilicon ingot; wherein, the ingot casting crucible reduces said temperature thereof gradient within a range of 50°-300° C./h in the temperature from 1000-1200° C. for gradually cooling said crystallized ingot therein.

In view of the above process, the integral polysilicon ingot of present invention can attain the dimension of (800 mm×800 mm×700 mm) to (1200 mm×1200 mm×900 mm) and the quantity of 1 to 3 tons thereof, which produces more ingots than other company in other countries, such as 275 KG of ingots produced by LDK Solar Corp. in China, 800 KG produced by companies in Germany, and 240˜280 KG produced by companies in JAPAN. Of further contradistinction, the present invention also has higher yield rate to produce pillar ingots with fewer or no holes and cracks therein, simultaneously reduces about more than 40% of energy consumption and 50% of manufacturing cost, thus achieving social and economic benefits.

### BRIEF DESCRIPTION OF THE DRAWINGS

FIG. 1 is a schematic view showing an ingot casting crucible of the present invention; and

FIG. 2 is a side view showing the ingot casting crucible of the present invention.

### DETAILED DESCRIPTION OF THE PREFERRED EMBODIMENTS

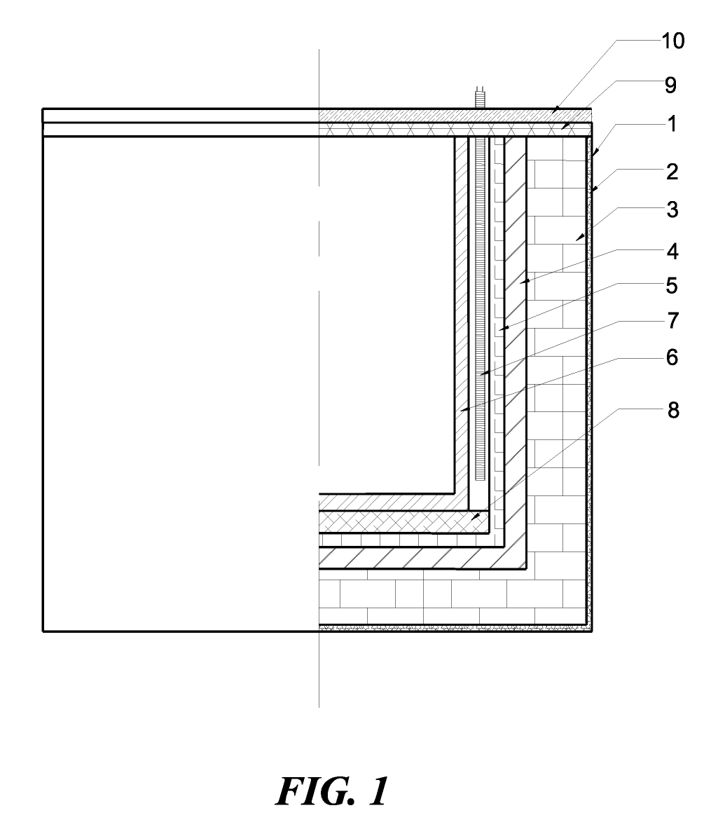

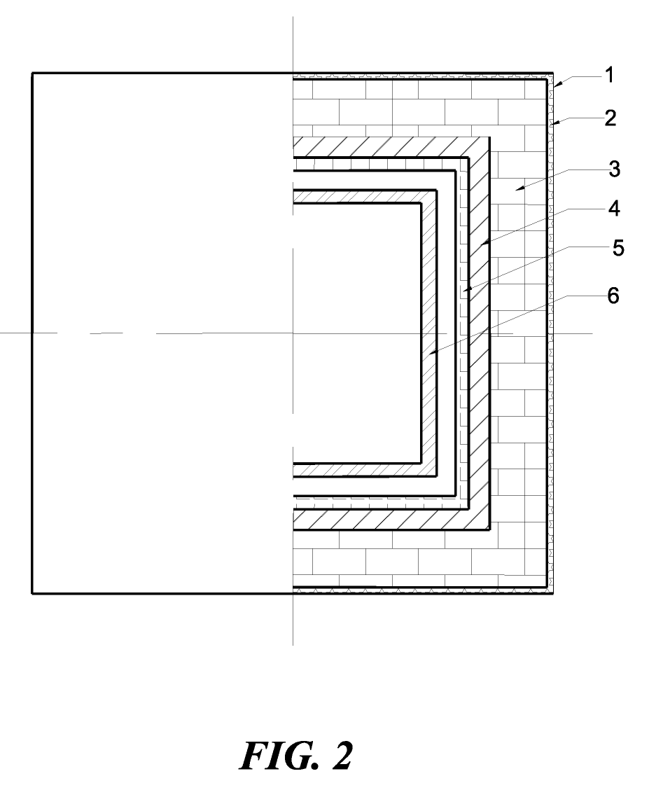

Referring to FIGS. 1 and 2, an ingot casting crucible of the present invention includes a crucible shield 1 comprised of metal boards with 5 mm of thickness, and contains in sequence an asbestos heat preservation board 2, three layers of standard firebricks 3, a refractory layer 4, a graphite heat preservation felt 5, a SiC (silicon carbide) heating 6, and a graphite mold 7; wherein, the graphite mold 7 has a graphite heating section 8 disposed thereunder and further attain a good heat insulation by assistances of the asbestos board 2, the firebricks 3, the refractory layer 4, and the graphite felt 5; simultaneously, the SiC heating 6 and the heating section 8 help adjusting the heating temperature, appropriately in the temperature range of 800°-1600° C. Furthermore, the graphite mold 7 is disposed in the middle of the crucible and has liquidized silicon therein; the mold 7 is comprised of a graphite board with characteristics of high purity, high strength, and high dense, and has two cover boards 9-10 disposed thereon; wherein, the two cover boards 9-10 are respectively made of corundum shaped firebrick and common refractory materials.

While in operation (not shown in figures), a first preferred embodiment of the present invention comprises the steps of charging 3 tons of liquidized silicon into 5 medium frequency induction furnaces for heating the liquidized silicon, further arranging 6% of solar-grade silicon slag removal fabricated of CaSiO3 (Calcium Silicate) for eliminating P-atomic(phosphorus) and other metal impurities inherent in the raw silicon materials; additionally, conducting some water vapor with the flow at 30 L/min into the raw silicon water inside the furnace for 26 minutes to attain a pure silicon water by obviating B-atomic (boride) and heating the pure silicon water in a water temperature at 1700° C.

Subsequently, pouring the pure silicon water into the graphite mold of the ingot casting crucible, which preserve in advance in the temperature at 1000° C.; the crucible is then heated to have the temperature at 1500° C. and retains the pure silicon water therein for about 1 hour, and then the crucible rapidly decreases the temperature gradient of 7° C./h from 1500° C., thence to 1400° C., and then to 1100° C., thereby solidifying the pure silicon water into the crystallized ingot; Still further, reducing the temperature of the crucible gradient of 100° C./h until reaching the lowest temperature at 300° C., finally taking the ingot out of the crucible and cooling it down, thus attaining 2.3 tons of integral polysilicon ingot.

A second preferred embodiment of the present invention includes the steps of charging 1.9 tons of the raw silicon materials into 4 medium frequency induction furnaces for heating and melting the raw materials into raw silicon water, and further arranging 10% of solar-grade silicon slag removal fabricated of BaCO3 (Barium Carbonate) for eliminating P-atomic(phosphorus) and other metal impurities inherent in the raw silicon materials; additionally, conducting some water vapor with the flow at 27 L/min into the raw silicon water inside the furnace for 25 minutes to attain a pure silicon water by obviating B-atomic (boride) and heating the pure silicon water in a water temperature at 1600° C.

Subsequently, pouring the pure silicon water into the graphite mold of the ingot casting crucible, which preserve in advance in the temperature at 1250° C.; the crucible is then heated to have the temperature at 1600° C. and retains the pure silicon water therein for about 2 hours, and then the crucible rapidly decreases the temperature gradient of 11° C./h from 1600° C., thence to 1420° C., and then to 1150° C., thereby solidifying the pure silicon water into the crystallized ingot; Still further, reducing the temperature of the crucible gradient of 200° C./h until reaching the lowest temperature at 280° C., finally taking the ingot out of the crucible and cooling it down, thus attaining 1.5 tons of integral polysilicon ingot.

A third preferred embodiment of the present invention includes the steps of charging 1.5 tons of the raw silicon materials into 3 medium frequency induction furnaces for melting and heating the raw materials into raw silicon water, further arranging respective 4% of solar-grade silicon slag removal made of BaCO3 (Barium Carbonate) and Na2SiO3 (Sodium Silicate)for eliminating P-atomic(phosphorus) and other metal impurities inherent in the raw silicon materials; additionally, conducting some water vapor with the flow at 15 L/min into the raw silicon water inside the furnace for 40 minutes to attain a pure silicon water by obviating B-atomic (boride) and heating the pure silicon water in a water temperature at 1500° C.

Subsequently, pouring the pure silicon water into the graphite mold of the ingot casting crucible, which preserve in advance in the temperature at 1400° C. and retains the pure silicon water therein for about 1 hour, and then the crucible rapidly decreases the temperature gradient of 40° C./h from 1480° C., thence to 1430° C., and then to 1000° C., thereby solidifying the pure silicon water into the crystallized ingot; Still further, reducing the temperature of the crucible gradient of 300° C./h until reaching the lowest temperature at 200° C., finally taking the ingot out of the crucible and cooling it down, thus attaining 1.2 tons of integral polysilicon ingot.

A fourth preferred embodiment of the present invention includes the steps of charging 2 tons of the liquidized silicon into a medium frequency induction furnace for heating the liquidized silicon, further arranging 15% of solar-grade silicon slag removal made of Na2B4′10H2O (Borax) for eliminating P-atomic(phosphorus) and other metal impurities inherent within the raw silicon materials; additionally, conducting some water vapor with the flow at 3.5 L/min into the raw silicon water inside the furnace for 38 minutes to attain a pure silicon water by obviating B-atomic (boride) and heating the pure silicon water in a water temperature at 1650° C.

Subsequently, pouring the pure silicon water into the graphite mold of the ingot casting crucible, which preserve in advance in the temperature at 1350° C.; the crucible is then heated to have the temperature at 1550° C. and retains the pure silicon water therein for about 1.2 hour, and then the crucible rapidly decreases the temperature gradient of 30° C./h from 1550° C., thence to 1410° C., and then to 1000° C., thereby solidifying the pure silicon water into the crystallized ingot; Still further, reducing the temperature of the crucible gradient of 150° C./h until reaching the lowest temperature at 300° C., finally taking the ingot out of the crucible and cooling it down, thus attaining 1.5 tons of integral polysilicon ingot.

A fifth preferred embodiment of the present invention includes the steps of charging 1.4 tons of the raw silicon materials into 2 medium frequency induction furnaces for melting and heating the raw materials into raw silicon water, and further arranging 3% of solar-grade silicon slag removal fabricated of Na2B4′10H2O (Borax) and 5% of CaSiO3 (Calcium Silicate) for eliminating P-atomic(phosphorus) and other metal impurities inherent within the raw silicon materials; additionally, conducting some water vapor with the flow at 60 L/min into the raw silicon water inside the furnace for 20 minutes to attain pure silicon water by obviating B-atomic (boride) and heating the pure silicon water in a water temperature at 1550° C.

Subsequently, pouring the pure silicon water into the graphite mold of the ingot casting crucible, which preserve in advance in the temperature at 1400° C.; the crucible is then heated to have the temperature at 1480° C. and retains the pure silicon water therein for about 1.3 hour, and then the crucible rapidly decreases the temperature gradient of 50° C./h from 1480° C., thence to 1425° C., and then to 1180° C., thereby solidifying the pure silicon water into the crystallized ingot; Still further, reducing the temperature of the crucible gradient of 50° C./h until reaching the lowest temperature at 280° C., finally taking the ingot out of the crucible and cooling it down, thus attaining 1.15 tons of integral polysilicon ingot.

A sixth preferred embodiment of the present invention includes the steps of charging 2.8 tons of liquidized silicon into 6 medium frequency induction furnaces for heating the liquidized silicon, and further arranging 2% of solar-grade silicon slag removal fabricated of CaSiO3 (Calcium Silicate) for eliminating P-atomic(phosphorus) and other metal impurities inherent in the raw silicon materials; additionally, conducting some water vapor with the flow at 40 L/min into the raw silicon water inside the furnace for 30 minutes to attain a pure silicon water by obviating B-atomic (boride) and heating the pure silicon water in a water temperature at 1650° C.

Subsequently, pouring the pure silicon water into the graphite mold of the ingot casting crucible, which preserve in advance in the temperature at 1200° C.; the crucible is then heated to have the temperature at 1500° C. and retains the pure silicon water therein for about 1 hour, and then the crucible rapidly decreases the temperature gradient of 7° C./h from 1500° C., thence to 1400° C., and then to 1080° C., thereby solidifying the pure silicon water into the crystallized ingot; Still further, reducing the temperature of the crucible gradient of 100° C./h until reaching the lowest temperature at 300° C., finally taking the ingot out of the crucible and cooling it down, thus attaining 2.2 tons of integral polysilicon ingot.

A seventh preferred embodiment of the present invention includes the steps of charging 1.5 tons of liquidized silicon into a medium frequency induction furnace for heating the liquidized silicon, and further arranging 5% of solar-grade silicon slag removal fabricated of Na2B4′10H2O (Borax) for eliminating P-atomic(phosphorus) and other metal impurities inherent within raw silicon materials; additionally, conducting some water vapor with the flow at 3.5 L/min into the raw silicon water inside the furnace for 5 minutes to attain a pure silicon water by obviating B-atomic (boride) and heating the pure silicon water in a water temperature at 1650° C.

Subsequently, pouring the pure silicon water into the graphite mold of the ingot casting crucible, which preserve in advance in the temperature at 1000° C.; the crucible is then heated to have the temperature at 1550° C. and retains the pure silicon water therein for about 1.2 hour, and then the crucible rapidly decreases the temperature gradient of 5° C./h from 1550° C., thence to 1410° C., and then to 1200° C., thereby solidifying the pure silicon water into the crystallized ingot; Still further, reducing the temperature of the crucible gradient of 150° C./h until reaching the lowest temperature at 400° C., finally taking the ingot out of the crucible and cooling it down, thus attaining 1.2 tons of integral polysilicon ingot.

While we have shown and described the embodiment in accordance with the present invention, it should be clear to those skilled in the art that further embodiments may be made without departing from the scope of the present invention.

I claim:

1. A method of manufacturing solar-grade polysilicon ingot with relevant induction apparatus comprising:
charging raw silicon materials or liquidized silicon into an induction furnace for melting said raw materials into raw silicon water or heating said liquidized silicon;
arranging a certain amount of solar-grade silicon slag removal into said furnace for mixing with said raw silicon water, thereby eliminating P-atomic(phosphorus) and other metal impurities inherent within said raw silicon materials;
conducting some water vapor into said raw silicon water inside said furnace for a removal of B-atomic (boride), further attaining a pure silicon water;
heating said pure silicon water in a water temperature range from 1500° C. to 1700° C.;
predetermining an ingot casting crucible and a graphite mold disposed therein to be electrically heated in a temperature range between 1000° C. and 1400° C., then pouring said pure silicon water into said graphite molds;
retaining said pure silicon water in said crucible for a while and controlling said water temperature range between 1450° C. and 1600° C.;
adjusting said crucible and said mold to attain said temperature range from 1400° C. to 1430° C.;
decreasing said temperature of said crucible and said molds gradient within 1000° C. to 1200° C., thereby generating a solid/liquid surface and interface property in said pure silicon water which would forward to a central of said mold; said metal impurities also concentrating on said central thereof; and then
gradually reducing said temperature of said crucible for solidifying said pure silicon water into a crystallized ingot; further retaining said ingot inside said crucible in said temperature range from 1000° C. to 1200° C. until reaching said temperature in a range of 200° C. to 400° C., and thereafter taking said ingot out of said crucible for a natural-cooling, thus finishing an integral solar-grade polysilicon ingot.

2. The method of manufacturing solar-grade polysilicon ingot with relevant induction apparatus as claimed in claim 1, wherein, more than 1 to 6 furnaces are utilized in said initial melting and heating process, and said furnaces belong to medium frequency induction furnaces.

3. The method of manufacturing solar-grade polysilicon ingot with relevant induction apparatus as claimed in claim 1, wherein, said solar-grade silicon slag removal is comprised of materials as CaSiO3 (Calcium Silicate), Na2SiO3 (Sodium Silicate), BaCO3 (Barium Carbonate), and Na2B4O7.10H2O (Borax), and either one or two said above materials are adopted therein.

4. The method of manufacturing solar-grade polysilicon ingot with relevant induction apparatus as claimed in claim 1, wherein, an appropriate ratio of said raw silicon water to said solar silicon slag removal is 100:2-15.

5. The method of manufacturing solar-grade polysilicon ingot with relevant induction apparatus as claimed in claim 1, wherein, said water vapor has a flow quantity at 3.5 L to 60 L/min., and total time for conducting said water vapor requires 5 to 40 minutes.

6. The method of manufacturing solar-grade polysilicon ingot with relevant induction apparatus as claimed in claim 1, wherein, said pure silicon water is heated to reach said water temperature at 1650° C.

7. The method of manufacturing solar-grade polysilicon ingot with relevant induction apparatus as claimed in claim 1, wherein, said pure silicon water is retained within said crucible appropriately for 1 to 2 hours and said water temperature is controlled, preferably at 1550° C.

8. The method of manufacturing solar-grade polysilicon ingot with relevant induction apparatus as claimed in claim 1, wherein, said temperature of said ingot casting crucible and said graphite mold is restricted at 1420° C.

9. The method of manufacturing solar-grade polysilicon ingot with relevant induction apparatus as claimed in claim 1, wherein, said temperature of said ingot casting crucible and said graphite molds is decreased gradient within a range of 5° to 50° C./h.

10. The method of manufacturing solar-grade polysilicon ingot with relevant induction apparatus as claimed in claim 1, wherein, said ingot casting crucible reduces said temperature gradient of 50° to 300° C./h in said temperature range from 1000° to 1200° C. for gradually cooling said crystallized ingot therein.
